(19) United States
(12) Patent Application Publication
(10) Pub. No.: US 2025/0113745 A1
(43) Pub. Date: Apr. 3, 2025

(54) VARIABLE RESISTANCE MATERIAL, SWITCH ELEMENT MATERIAL, SWITCH LAYER, SWITCH ELEMENT, AND STORAGE DEVICE

(71) Applicants: TOHOKU UNIVERSITY, Sendai-shi, Miyagi (JP); NIPPON ELECTRIC GLASS CO., LTD., Otsu-shi, Shiga (JP)

(72) Inventors: Yuji SUTOU, Sendai-shi (JP); Yi SHUANG, Sendai-shi (JP); Yoshimasa MATSUSHITA, Otsu-shi (JP); Fumio SATO, Otsu-shi (JP)

(21) Appl. No.: 18/729,198

(22) PCT Filed: Jan. 26, 2023
(86) PCT No.: PCT/JP2023/002349

§ 371 Date: Jul. 16, 2024

(30) Foreign Application Priority Data
Jan. 28, 2022 (JP) 2022-011932

(51) Int. Cl. H10N 70/00; H10B 63/00

(52) U.S. Cl. CPC H10N 70/882; H10B 63/24; H10B 63/30; H10B 63/84; H10N 70/026; H10N 70/841

(57) ABSTRACT

Provided is a variable resistance material, a switch element material, a switch layer, a switch element, and a memory device which have a large ON/OFF current ratio and can obtain a stable switching effect. A variable resistance material contains, in terms of % by atom, 1% to 40% Ge, 40% to 90% Te, and 1% to 59% Si+Al+Ga+Sn+Bi+Cu+Ag+Zn+Y+In+Ca+Mg.

### TECHNICAL FIELD

The present invention relates to variable resistance materials, switch element materials, switch layers, switch elements, and memory devices.

### BACKGROUND ART

Next-generation non-volatile memory devices are attracting attention as alternative memory devices to a NAND flash memory. For example, a resistance-variable memory device and a phase-variable memory device are proposed as next-generation non-volatile memory devices and are being under development for increasing the capacity and the processing speed.

Furthermore, a cross-point memory device is also attracting attention as a structure for a next-generation non-volatile memory device (Patent Literatures 1 and 2). The cross-point memory device includes word lines, bit lines orthogonal to the word lines in plan view, and memory elements and switch elements arranged at the intersections between the word lines and the bit lines in plan view. A transistor or a diode is conventionally used as the switch element, but the use of an ovonic threshold switch (OTS) element variable in resistance according to the applied voltage is beginning to attract attention with increasing size reduction, capacity, and integration of memory devices.

### CITATION LIST

### Patent Literature

### [PTL 1]

JP-A-2006-086526

### [PTL 2]

JP-A-2018-164085

### SUMMARY OF INVENTION

### Technical Problem

For an OTS element, a switch element exhibiting stable resistance changes with applied voltage is required in order to obtain a stable switching effect. Furthermore, an OTS element carrying a large current during turn-on and carrying a small current during turn-off (i.e., an OTS element having a large ON/OFF current ratio) is desired.

In view of the foregoing, the present invention has an object of providing a variable resistance material, a switch element material, a switch layer, a switch element, and a memory device which have a large ON/OFF current ratio and can obtain a stable switching effect.

### Solution to Problem

A description will be given below of aspects of a variable resistance material, a switch element material, a switch layer, a switch element, and a memory device that can solve the above challenge.

A variable resistance material of Aspect 1 has a feature of containing, in terms of % by atom, 1% to 40% Ge, 40% to 90% Te, and 1% to 59% Si+Al+Ga+Sn+Bi+Cu+Ag+Zn+Y+In+Ca+Mg. As used herein, “Si+Al+Ga+Sn+Bi+Cu+Ag+Zn+Y+In+Ca+Mg” refers to a total content of Si, Al, Ga, Sn, Bi, Cu, Ag, Zn, Y, In, Ca, and Mg.

A variable resistance material of Aspect 2 is the variable resistance material according to Aspect 1, wherein the variable resistance material preferably contains, in terms of % by atom, 0% to 20% Sb.

A variable resistance material of Aspect 3 is the variable resistance material according to Aspect 1 or 2, wherein the variable resistance material is preferably substantially free of Sb, Se, and As.

A variable resistance material of Aspect 4 is the variable resistance material according to any one of Aspects 1 to 3, wherein the variable resistance material preferably contains, in terms of % by atom, over 50% to 90% Te.

A variable resistance material of Aspect 5 is the variable resistance material according to any one of Aspects 1 to 4, wherein the variable resistance material preferably contains, in terms of % by atom, 1% to less than 30% Ge.

A variable resistance material of Aspect 6 is the variable resistance material according to any one of Aspects 1 to 5, wherein the variable resistance material preferably has an ON/OFF current ratio of 1×10⁴ or more. As used herein, the ON/OFF current ratio means a value obtained by dividing a value of an ON current by a value of an OFF current where the ON current is a value of a current flowing through the material upon application of a threshold voltage or higher thereto and the OFF current is a value of a current flowing through the material upon application of one-half the threshold voltage thereto.

A variable resistance material of Aspect 7 is the variable resistance material according to any one of Aspects 1 to 6, wherein the variable resistance material preferably has a crystallization temperature Tx of 150° C. or higher.

A switch element material of Aspect 8 has a feature of being made of the variable resistance material according to any one of Aspects 1 to 7.

A switch layer of Aspect 9 has a feature of being made of the variable resistance material according to any one of Aspects 1 to 7.

A switch element of Aspect 10 has a feature of including: a first electrode; and the switch layer according to Aspect 9 and disposed on the first electrode.

A switch element of Aspect 11 is the switch element according to Aspect 10, wherein the switch element preferably includes a second electrode disposed at a position opposed to the first electrode with the switch layer in between.

A memory device of Aspect 12 has a feature of including: the switch element according to Aspect 10 or 11; and a memory element.

### Advantageous Effects of Invention

The present invention enables provision of a variable resistance material, a switch element material, a switch layer, a switch element, and a memory device which have a large ON/OFF current ratio and can obtain a stable switching effect.

### BRIEF DESCRIPTION OF DRAWINGS

FIG. 1 is a schematic cross-sectional view of a switch element according to one embodiment of the present invention.

FIG. 2 is a schematic stereogram of a memory device according to one embodiment of the present invention.

FIG. 3 is a schematic partially enlarged view of the memory device according to the one embodiment of the present invention.

### DESCRIPTION OF EMBODIMENTS

Hereinafter, a description will be given of preferred embodiments. However, the following embodiments are merely illustrative and the present invention is not limited to the following embodiments.

### <Variable Resistance Material>

A variable resistance material according to the present invention has a feature of containing, in terms of % by atom, 1% to 40% Ge, 40% to 90% Te, and 1% to 59% Si+Al+Ga+Sn+Bi+Cu+Ag+Zn+Y+In+Ca+Mg. In other words, the variable resistance material according to the present invention has a feature of containing, in terms of % by atom, 1% to 40% Ge and 40% to 90% Te and further containing, in terms of % by atom, 1% to 59% at least one selected from among Si, Al, Ga, Sn, Bi, Cu, Ag, Zn, Y, In, Ca, and Mg. The reasons why the composition is defined as just described and the respective contents of components will be described below. In the following description, “%” refers to “% by atom” unless otherwise stated. In the present invention, “x+y+z+ . . . ” means the total content of components. In this case, the variable resistance material need not necessarily contain all of the components as essential components and may not contain one or some of the components (that is, the content of the one or some of the components may be 0%). The expression “A % to B % x+y+z+ . . . ” includes, for example, the case of “x=0% and A % to B % y+z+ . . . ” and the case of “x=0%, y=0%, and A % to B % z+ . . . ”.

Ge is an essential component that stabilizes the amorphous state of the variable resistance material. The content of Ge is 1% to 40%, preferably 1% to 39%, 1% to 35%, 1% to 30%, 1% to less than 30%, 2% to less than 30%, 5% to less than 30%, 7.5% to less than 30%, 7.5% to 29%, 7.5% to 28%, and particularly preferably 10% to 25%. If the content of Ge is too small, the amorphous state is likely to be unstable. If the content of Ge is too large, the OTS characteristics are difficult to obtain. In addition, the production cost is likely to increase. The OTS characteristics mean characteristics where the resistance value changes with the application of voltage. The details thereof are as follows. The variable resistance material exhibits high resistance in an initial state (an OFF state). When in this state voltage is gradually applied to the variable resistance material, the variable resistance material maintains a high-resistance state before the applied voltage reaches a threshold voltage, but then abruptly switches to a low-resistance state (an ON state) as soon as the applied voltage exceeds the threshold value. When the applied voltage is lowered from the ON state, the variable resistance material returns to the OFF state again. Therefore, the material having OTS characteristics can be used as a switch layer and a switch element. As the variable resistance material has a larger ON/OFF current ratio, it has more excellent characteristics as a switch element.

Te is an essential component that constitutes part of the variable resistance material. The content of Te is 40% to 90%, preferably 45% to 90%, 47% to 90%, 50% to 90%, over 50% to 90%, 51% to 89%, 53% to 82.5%, 55% to 80%, and particularly preferably 60% to 80%. If the content of Te is too small, the amorphous state is likely to be unstable. In addition, the OTS characteristics are difficult to obtain. If the content of Te is too large, the amorphous state is likely to be unstable. In addition, the OTS characteristics are difficult to obtain.

The content of Ge+Te (the total content of Ge and Te) is preferably 41% to 99%, 45% to 99%, 50% to 99%, 60% to 99%, 65% to 99%, 70% to 98%, 75% to 97%, and particularly preferably 80% to 95%. If the content of Ge+Te is too small, the amorphous state is likely to be unstable. In addition, the OTS characteristics are difficult to obtain. If the content of Ge+Te is too large, the OTS characteristics are difficult to obtain.

Si, Al, Ga, Sn, Bi, Cu, Ag, Zn, Y, In, Ca, and Mg stabilize the amorphous state of the variable resistance material and improve the number of cycles. In the present invention, the number of cycles means the number of repetitions of switching between ON/OFF currents until the ON/OFF current ratio reaches 10% of its initially measured value. In addition, these components are those that decrease the OFF current and thus can easily increase the ON/OFF current ratio. Therefore, in the variable resistance material according to the present invention, the content of Si+Al+Ga+Sn+Bi+Cu+Ag+Zn+Y+In+Ca+Mg (the total content of Si, Al, Ga, Sn, Bi, Cu, Ag, Zn, Y, In, Ca, and Mg) is preferably 1% to 59%, 1% to 58%, 1% to 55%, 1% to 50%, 1% to 45%, 1% to 40%, 1% to 35%, 1% to 30%, 1% to 25%, 1% to 20%, 1% to 15%, 2% to 15%, 2% to 14%, 2% to 13%, and particularly preferably 2% to 10%. The content just described may be restated as follows: The variable resistance material contains at least one of components selected from among Si, Al, Ga, Sn, Bi, Cu, Ag, Zn, Y, In, Ca, and Mg. If the content of these components is too small, the above effects are difficult to obtain. If the content of these components is too large, the amorphous state is likely to be unstable. In addition, the OTS characteristics are difficult to obtain. The content of each component of Si, Al, Ga, Sn, Bi, Cu, Ag, Zn, Y, In, Ca, and Mg is preferably 0% to 59%, 1% to 59%, 1% to 58%, 1% to 55%, 1% to 50%, 1% to 45%, 1% to 40%, 1% to 35%, 1% to 30%, 1% to 25%, 1% to 20%, 1% to 15%, 2% to 15%, 2% to 14%, 2% to 13%, 2% to 10%, 2% to less than 10%, and particularly preferably 2% to 9%.

Among the components just described, Ga and Ag are components that decrease the carrier mobility and can easily decrease the OFF current. Therefore, particularly, these components contribute to further improvement of the ON/OFF current ratio. In addition, these components particularly stabilize the amorphous state and are therefore components that can easily increase the number of cycles. The content of Ga+Ag (the total content of Ga and Ag) is preferably not less than 0%, not less than 1%, not less than 2%, not less than 3%, and particularly preferably not less than 5%, preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13%, and particularly preferably not more than 10%.

Particularly, from the viewpoint of further decreasing the OFF current, the ratio Ga/(Ga+Ag) is preferably not less than 0.1, particularly preferably not less than 0.2, preferably not more than 1, more preferably less than 1, and particularly preferably not more than 0.9.

Particularly, from the viewpoint of further increasing the number of cycles, the ratio Ag/(Ga+Ag) is preferably not less than 0.1, particularly preferably not less than 0.2, preferably not more than 1, more preferably less than 1, and particularly preferably not more than 0.9.

The variable resistance material according to the present invention may contain, in addition to the components described thus far, the following components.

Sb is a component likely to make the amorphous state unstable at high temperatures. Therefore, the content of Sb is preferably 0% to 20%, 0% to 15%, 0% to 10%, 0% to 8%, 0% to 5%, 0% to 3%, and 0% to 2%, and the variable resistance material is particularly preferably substantially free of Sb. Herein, “substantially free of” means that no amount of the relevant component is deliberately contained in the variable resistance material, and is not intended to exclude even the incorporation thereof in impurity level. Objectively, this means that the content of the component is less than 0.1%.

Se is a component that easily stabilizes the amorphous state of the variable resistance material. The content of Se is preferably 0% to 58%, 1% to 55%, 5% to 50%, 10% to 50%, and particularly preferably 20% to 50%. If the content of Se is too large, the amorphous state is likely to be unstable. Furthermore, Se is a toxic component. Therefore, from the viewpoint of reducing the burden on the environment, the content of Se is preferably not more than 40%, not more than 30%, not more than 20%, and not more than 10%, and the variable resistance material is particularly preferably substantially free of Se.

As is a component that easily stabilizes the amorphous state of the variable resistance material. However, because As is a toxic component, the content of As is, from the viewpoint of reducing the burden on the environment, preferably not more than 30%, not more than 25%, not more than 20%, not more than 10%, not more than 5%, and not more than 3%, and the variable resistance material is particularly preferably substantially free of As.

The variable resistance material according to the present invention is preferably substantially free of Sb, Se, and As. Thus, the burden on the environment can be more easily reduced.

F, Cl, Br, and I are components that easily stabilize the amorphous state of the variable resistance material. The content of F+Cl+Br+I (the total content of F, Cl, Br, and I) is preferably 0% to 40%, more preferably 0% to 30%, even more preferably 0% to 20%, and particularly preferably 0% to 10%. If the content of F+Cl+Br+I is too large, the amorphous state is contrariwise likely to be unstable. In addition, the weather resistance is likely to decrease. The content of each component of F, Cl, Br, and I is preferably 0% to 40%, more preferably 0% to 30%, even more preferably 0% to 20%, and particularly preferably 0% to 10%.

The variable resistance material according to the present invention may contain B, C, P, Cr, Mn, Ti, or Fe. The content of B+C+P+Cr+Mn+Ti+Fe (the total content of B, C, P, Cr, Mn, Ti, and Fe) is preferably 0% to 10%, 0% to 5%, 0% to 1%, 0% to less than 1%, and 0% to 0.1% and the variable resistance material is particularly preferably substantially free of these components. If the content of these components is too large, the amorphous state is likely to be unstable. The content of each component of B, C, P, Cr, Mn, Ti, and Fe is preferably 0% to 10%, 0% to 5%, 0% to 1%, 0% to less than 1%, and 0% to 0.1% and the variable resistance material is particularly preferably substantially free of the component.

The variable resistance material according to the present invention is preferably substantially free of Cd, Tl, and Pb. Thus, the burden on the environment can be further reduced.

Since the variable resistance material according to the present invention contains, in terms of % by atom, 1% to 40% Ge, 40% to 90% Te, and 1% to 59% Si+Al+Ga+Sn+Bi+Cu+Ag+Zn+Y+In+Ca+Mg, it exhibits OTS characteristics suitable as a switch element material. In other words, the variable resistance material according to the present invention has a large ON/OFF current ratio and exhibits a stable switching effect. Specifically, the ON/OFF current ratio is preferably not less than 1×10⁴, more preferably not less than 1×10⁵, and particularly preferably not less than 1×10⁶. When the ON/OFF current ratio meets the above values, more excellent OTS characteristics can be obtained.

Furthermore, in the variable resistance material according to the present invention, the ratio between the electric resistance value upon application of a threshold voltage or higher (ON resistance) and the electric resistance value upon application of one-half the threshold voltage (OFF resistance) (i.e., a value obtained by dividing the value of ON resistance by the value of OFF resistance) is preferably not more than 1×10⁻⁴, more preferably not more than 1×10⁻⁵, and particularly preferably not more than 1×10⁻⁶. Moreover, the current value upon application of the voltage is preferably not less than 1×10⁴ A/cm² and particularly preferably not less than 1×10⁵ A/cm². When these values are satisfied, a sufficient drive current can be obtained in a low-resistance state.

In the variable resistance material according to the present invention, the crystallization temperature Tx is preferably 150° C. or higher, more preferably 160° C. or higher, and particularly preferably 170° C. or higher. When the crystallization temperature Tx meets the above values, crystallization due to exotherm caused at switching is less likely to occur and the number of cycles is further increased. The upper limit of the crystallization temperature Tx is not particularly limited, but may be, for example, not higher than 500° C. or particularly not higher than 450° C.

In the variable resistance material according to the present invention, the carrier mobility at 30° C. is preferably 5×10⁻³ cm²/Vs or less, more preferably 1×10⁻³ cm²/Vs or less, even more preferably 5×10⁻⁴ cm²/Vs or less, and particularly preferably 1×10⁻⁴ cm²/Vs or less. When the carrier mobility meets the above values, the value of OFF current is easily decreased and the ON/OFF current ratio is easily increased. Therefore, more excellent OTS characteristics can be obtained. The lower limit of the carrier mobility is not particularly limited, but may be, for example, not less than 1×10⁻⁷ cm²/Vs or particularly not less than 1×10⁻⁶ cm²/Vs.

Since the variable resistance material according to the present invention has a stable amorphous state, the number of cycles can be increased. In other words, the ON/OFF current ratio can be maintained even when turning-on and turning-off are repeated. Specifically, the number of cycles (the number of repetitions of switching between ON/OFF currents until the ON/OFF current ratio reaches 10% of its initially measured value) is preferably 1×10³ or more and particularly preferably 1×10⁴ or more. If the number of cycles is too small, the variable resistance material is difficult to use as a switch element. The upper limit of the number of cycles is not particularly limited, but may be, for example, not more than 1×10⁸ or particularly not more than 1×10⁷.

The variable resistance material according to the present invention can be produced, for example, in the following manner. First, raw materials are formulated to give a desired composition. Next, the formulated raw materials are put into a quartz glass ampule evacuated while being heated, and the ampule is sealed with an oxygen burner while being evacuated. Next, the sealed quartz glass ampule is held at about 650° C. to about 1000° C. for six hours to twelve hours. Thereafter, the ampule is rapidly cooled to room temperature. Thus, a bulk variable resistance material can be obtained.

Elemental materials (such as Ge, Ga, Si, Te, Ag or I) may be used as raw materials or compound materials (such as GeTe₄, Ga₂Te₃ or AgI) may be used as raw materials. Alternatively, these types of materials may be used in combination.

Using the obtained variable resistance material as a sputtering target, a thin film (a switch layer) having the above-described composition can be formed.

Alternatively, by a multi-sputtering process using pure elemental M targets (Ge, Te, Sb, Si, Al, Ga, Sn, Bi, Cu, Ag, Zn, Y, In, Ca, and Mg), a binary alloy target or a ternary or higher alloy target as a sputtering target, a thin film (a switch layer) having the above-described composition can be formed by appropriately controlling the deposition output to adjust the components.

Still alternatively, a thin film can be formed using a powder of metals or compounds formulated at an arbitrary ratio as a sputtering target.

The method for producing a thin film is not particularly limited and, except for the sputtering process, the CVD (chemical vapor deposition) process, the ALD (atomic layer deposition) process or others can be selected. Among others, the sputtering process is preferably used because the composition and the film thickness can be easily controlled.

As thus far described, the variable resistance material according to the present invention contains, in terms of % by atom, 1% to 40% Ge, 40% to 90% Te, and 1% to 59% Si+Al+Ga+Sn+Bi+Cu+Ag+Zn+Y+In+Ca+Mg. Since the variable resistance material according to the present invention has the above structure, it exhibits OTS characteristics and the amorphous state can be easily made stable. Therefore, the variable resistance material according to the present invention can be suitably used for a switch element. In other words, the variable resistance material according to the present invention is suitable as a switch element material.

### <Switch Element and Memory Device>

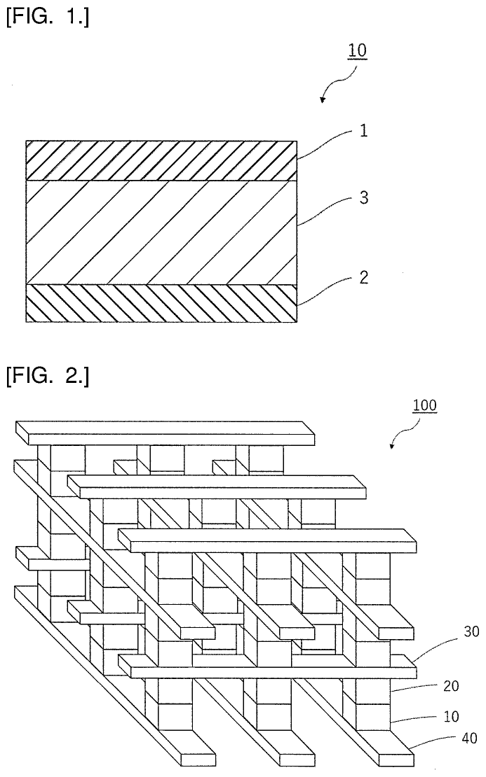

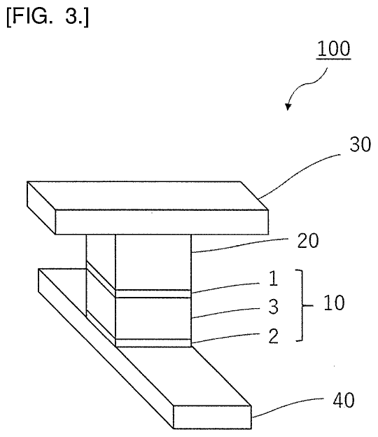

FIG. 1 is a schematic cross-sectional view of a switch element according to one embodiment of the present invention. A switch element 10 includes a first electrode 1, a second electrode 2, and a switch layer 3. The second electrode 2 is disposed at a position opposite to the first electrode 1. In this embodiment, the switch layer 3 is disposed between the first electrode 1 and the second electrode 2. FIG. 2 is a schematic stereogram of a memory device according to one embodiment of the present invention and FIG. 3 is a schematic partially enlarged view of the memory device according to the one embodiment of the present invention. As shown in FIGS. 2 and 3, a memory device 100 includes switch elements 10, memory elements 20, word lines 30, and bit lines 40. The bit lines 40 are orthogonal to the word lines 30 in plan view. The switch elements 10 and the memory elements 20 are arranged at the intersections between the word lines 30 and the bit lines 40. Accordingly, the memory device 100 according to the present invention is a cross-point memory device.

An inorganic material may be used for the first electrode 1 and the second electrode 2. Examples that can be used as the inorganic material include a metallic material and a ceramic material. For example, tungsten, titanium, copper or platinum is preferably used as the metallic material. For example, tungsten nitride or titanium nitride is preferably used as the ceramic material.

The thicknesses of the first electrode 1 and the second electrode 2 can be appropriately designed. The thickness of each of the first electrode 1 and the second electrode 2 is, for example, preferably 200 nm or less, more preferably 100 nm or less, even more preferably 80 nm or less, still even more preferably 60 nm or less, and particularly preferably 50 nm or less. The smaller thickness is more advantageous to increase in capacity of a memory device. The lower limit of thickness of each of the first electrode 1 and the second electrode 2 is, for example, preferably not less than 1 nm and particularly preferably not less than 2 nm.

The switch layer 3 is made of the variable resistance material according to the present invention and, therefore, exhibits the above-described OTS characteristics. In the present invention, the switch layer 3 is amorphous and does not undergo any phase change due to the application of voltage. In other words, even when voltage is applied to the switch layer 3, the switch layer 3 does not change the phase into a crystal phase.

The switch layer 3 is disposed in contact with at least one electrode. In other words, the switch layer 3 is disposed on at least one of the first electrode 1 and the second electrode 2.

The thickness of the switch layer 3 can be appropriately designed according to a desired threshold voltage. The thickness of the switch layer 3 is, for example, preferably 300 nm or less, more preferably 200 nm or less, and particularly preferably 100 nm or less. If the thickness is too large, the threshold voltage is likely to be excessively large. The lower limit of the thickness of the switch layer 3 is, for example, preferably not less than 1 nm, more preferably not less than 2 nm, even more preferably not less than 5 nm, still even more preferably not less than 10 nm, yet still even more preferably not less than 30 nm, and particularly preferably more than 50 nm.

### EXAMPLES

Hereinafter, the present invention will be described with reference to examples, but the present invention is not limited to these examples.

Tables 1 to 11 show Examples Ex. 1 to Ex. 107 of the present invention and Comparative Examples CEx. 1 and CEx. 2.

TABLE 1

| | | Ex. 1 | Ex. 2 | Ex. 3 | Ex. 4 | Ex. 5 | Ex. 6 | Ex. 7 | Ex. 8 | Ex. 9 | Ex. 10 |
|---|---|---|---|---|---|---|---|---|---|---|---|
| Variable | Ge | 23.0 | 16.0 | 15.8 | 22.4 | 22.7 | 16.0 | 15.7 | 22.4 | 25.0 | 21.8 |
| Resistance | Te | 66.7 | 73.0 | 73.3 | 67.7 | 66.5 | 73.1 | 73.4 | 66.6 | 64.0 | 68.3 |
| Material | Si | 2.9 | 5.2 | | | | | | | | |
| Composition | Al | | | | | | 5.3 | | | 9.0 | |
| (% by atom) | Ga | | | 5.7 | 7.1 | | | 6.0 | 8.5 | | 7.7 |
| | Sn | | | | 2.8 | | | 4.9 | | 2.0 | |
| | Bi | 7.4 | | | | | | | | | |
| | Ag | | | 5.2 | | 3.9 | 5.6 | | 2.5 | | 2.2 |
| | Sb | | 5.8 | | | 6.9 | | | | | |

| | | | | | | | | | | |
|---|---|---|---|---|---|---|---|---|---|---|
| Ge + Te | 89.7 | 89.0 | 89.1 | 90.1 | 89.2 | 89.1 | 89.1 | 89.0 | 89.0 | 90.1 |
| Si + Al + Ga + Sn + | 10.3 | 5.2 | 10.9 | 9.9 | 3.9 | 10.9 | 10.9 | 11.0 | 11.0 | 9.9 |
| Bi + Cu + Ag + Zn + | | | | | | | | | | |
| Y + In + Ca + Mg | | | | | | | | | | |
| Ga + Ag | 0.0 | 0.0 | 10.9 | 7.1 | 3.9 | 5.6 | 6.0 | 11.0 | 0.0 | 9.9 |
| Ga/(Ga + Ag) | — | — | 0.5 | 1.0 | 0.0 | 0.0 | 1.0 | 0.8 | — | 0.8 |
| Ag/(Ga + Ag) | — | — | 0.5 | 0.0 | 1.0 | 1.0 | 0.0 | 0.2 | — | 0.2 |
| Tx(° C.) | 262 | 224 | 245 | 274 | 243 | 242 | 246 | 250 | 246 | 275 |

TABLE 2

| | | Ex. 11 | Ex. 12 | Ex. 13 | Ex. 14 | Ex. 15 | Ex. 16 | Ex. 17 | Ex. 18 | Ex. 19 | Ex. 20 |
|---|---|---|---|---|---|---|---|---|---|---|---|
| Variable | Ge | 24.8 | 24.5 | 22.9 | 23.2 | 23.1 | 24.4 | 24.6 | 23.3 | 24.2 | 23.3 |
| Resistance | Te | 63.6 | 64.6 | 66.7 | 66.4 | 66.6 | 64.0 | 63.8 | 65.7 | 66.4 | 66.3 |
| Material | Si | 2.6 | | | 2.3 | | 4.1 | | | | |
| Composition | Al | | | | | | 7.5 | | | | |
| (% by atom) | Ga | 9.0 | | 6.4 | | | | 8.6 | | | 7.7 |
| | Sn | | 3.5 | 4.0 | | | | | | 1.8 | |
| | Bi | | | | 8.1 | | | | 4.3 | | |
| | Ag | | | | | 3.3 | | 3.0 | 6.7 | | 2.7 |
| | Sb | | 7.4 | | | 7.0 | | | | 7.6 | |

| | | | | | | | | | | |
|---|---|---|---|---|---|---|---|---|---|---|
| Ge + Te | 88.4 | 89.1 | 89.6 | 89.6 | 89.7 | 88.4 | 88.4 | 89.0 | 90.6 | 89.6 |
| Si + Al + Ga + Sn + | 11.6 | 3.5 | 10.4 | 10.4 | 3.3 | 11.6 | 11.6 | 11.0 | 1.8 | 10.4 |
| Bi + Cu + Ag + Zn + | | | | | | | | | | |
| Y + In + Ca + Mg | | | | | | | | | | |
| Ga + Ag | 9.0 | 0.0 | 6.4 | 0.0 | 3.3 | 0.0 | 11.6 | 6.7 | 0.0 | 10.4 |
| Ga/(Ga + Ag) | 1.0 | — | 1.0 | — | 0.0 | — | 0.7 | 0.0 | — | 0.7 |
| Ag/(Ga + Ag) | 0.0 | — | 0.0 | — | 1.0 | — | 0.3 | 1.0 | — | 0.3 |
| Tx(° C.) | 295 | 278 | 299 | 294 | 276 | 297 | 299 | 243 | 216 | 308 |

TABLE 3

| | | Ex. 21 | Ex. 22 | Ex. 23 | Ex. 24 | Ex. 25 | Ex. 26 | Ex. 27 | Ex. 28 | Ex. 29 | Ex. 30 |
|---|---|---|---|---|---|---|---|---|---|---|---|
| Variable | Ge | 24.4 | 14.7 | 25.0 | 25.1 | 24.6 | 15.0 | 25.2 | 24.1 | 26.3 | 25.5 |
| Resistance | Te | 64.2 | 77.5 | 63.0 | 63.5 | 64.2 | 77.2 | 62.8 | 64.5 | 61.7 | 62.2 |
| Material | Si | | | | | | | | 2.6 | | |
| Composition | Al | | | | | | | | | 8.4 | |
| (% by atom) | Ga | 9.1 | 5.3 | | | | | 8.9 | 8.8 | | |
| | Sn | | | 2.9 | | 3.2 | | | | 3.6 | |
| | Bi | | | 9.1 | 9.4 | | 5.1 | | | | |
| | Ag | 2.3 | 2.5 | | 2.0 | | 2.7 | 3.1 | | | 3.7 |
| | Sb | | | | | 8.0 | | | | | 8.6 |

| | | | | | | | | | | |
|---|---|---|---|---|---|---|---|---|---|---|
| Ge + Te | 88.6 | 92.2 | 88.0 | 88.6 | 88.8 | 92.2 | 88.0 | 88.6 | 88.0 | 87.7 |
| Si + Al + Ga + Sn + | 11.4 | 7.8 | 12.0 | 11.4 | 3.2 | 7.8 | 12.0 | 11.4 | 12.0 | 3.7 |
| Bi + Cu + Ag + Zn + | | | | | | | | | | |
| Y + In + Ca + Mg | | | | | | | | | | |
| Ga + Ag | 11.4 | 7.8 | 0.0 | 2.0 | 0.0 | 2.7 | 12.0 | 8.8 | 0.0 | 3.7 |
| Ga/(Ga + Ag) | 0.8 | 0.7 | — | 0.0 | — | 0.0 | 0.7 | 1.0 | — | 0.0 |
| Ag/(Ga + Ag) | 0.2 | 0.3 | — | 1.0 | — | 1.0 | 0.3 | 0.0 | — | 1.0 |
| Tx(° C.) | 243 | 245 | 284 | 233 | 221 | 238 | 291 | 241 | 282 | 265 |

TABLE 4

| | | Ex. 31 | Ex. 32 | Ex. 33 | Ex. 34 | Ex. 35 | Ex. 36 | Ex. 37 | Ex. 38 | Ex. 39 | Ex. 40 |
|---|---|---|---|---|---|---|---|---|---|---|---|
| Variable | Ge | 17.4 | 17.3 | 18.0 | 17.1 | 16.8 | 14.5 | 17.0 | 16.5 | 14.8 | 17.2 |
| Resistance | Te | 73.1 | 73.3 | 72.5 | 74.2 | 74.5 | 77.1 | 74.3 | 74.8 | 77.4 | 73.3 |
| Material | Si | | 2.6 | | | | 2.9 | | 2.7 | | |
| Composition | Al | | | | 5.5 | | | | | | |
| (% by atom) | Ga | | | 6.8 | | | | 5.7 | 6.0 | 5.2 | |
| | Sn | | | | | 3.1 | | | | 2.6 | 2.0 |
| | Bi | 7.0 | | | | | | | | | 7.5 |
| | Ag | 2.5 | | 2.7 | 3.2 | | | 3.0 | | | |
| | Sb | | 6.8 | | | 5.6 | 5.5 | | | | |

| | | | | | | | | | | |
|---|---|---|---|---|---|---|---|---|---|---|
| Ge + Te | 90.5 | 90.6 | 90.5 | 91.3 | 91.3 | 91.6 | 91.3 | 91.3 | 92.2 | 90.5 |
| Si + Al + Ga + Sn + | 9.5 | 2.6 | 9.5 | 8.7 | 3.1 | 2.9 | 8.7 | 8.7 | 7.8 | 9.5 |
| Bi + Cu + Ag + Zn + | | | | | | | | | | |
| Y + In + Ca + Mg | | | | | | | | | | |
| Ga + Ag | 2.5 | 0.0 | 9.5 | 3.2 | 0.0 | 0.0 | 8.7 | 6.0 | 5.2 | 0.0 |
| Ga/(Ga + Ag) | 0.0 | — | 0.7 | 0.0 | — | — | 0.7 | 1.0 | 1.0 | — |
| Ag/(Ga + Ag) | 1.0 | — | 0.3 | 1.0 | — | — | 0.3 | 0.0 | 0.0 | — |
| Tx(° C.) | 271 | 247 | 275 | 245 | 234 | 222 | 250 | 249 | 248 | 269 |

TABLE 5

| | | Ex. 41 | Ex. 42 | Ex. 43 | Ex. 44 | Ex. 45 | Ex. 46 | Ex. 47 | Ex. 48 | Ex. 49 | Ex. 50 |
|---|---|---|---|---|---|---|---|---|---|---|---|
| Variable | Ge | 18.0 | 17.6 | 16.5 | 18.3 | 17.4 | 17.6 | 17.5 | 17.4 | 16.2 | 17.8 |
| Resistance | Te | 75.9 | 72.5 | 74.6 | 72.1 | 72.7 | 72.5 | 74.1 | 73.0 | 74.9 | 72.6 |
| Material | Si | | | | | 3.4 | | | | 3.1 | |
| Composition | Al | | | | 5.8 | | | | | | |
| (% by atom) | Ga | | 6.3 | 6.2 | | 6.5 | 6.0 | | 6.0 | 5.8 | 6.2 |
| | Sn | | | | 3.8 | | 3.9 | 2.5 | 3.6 | | |
| | Bi | | | | | | | | | | |
| | Ag | 2.6 | 3.6 | 2.7 | | | | | | | 3.4 |
| | Sb | 3.5 | | | | | | 5.9 | | | |

| | | | | | | | | | | |
|---|---|---|---|---|---|---|---|---|---|---|
| Ge + Te | 93.9 | 90.1 | 91.1 | 90.4 | 90.1 | 90.1 | 91.6 | 90.4 | 91.1 | 90.4 |
| Si + Al + Ga + Sn + | 2.6 | 9.9 | 8.9 | 9.6 | 9.9 | 9.9 | 2.5 | 9.6 | 8.9 | 9.6 |
| Bi + Cu + Ag + Zn + | | | | | | | | | | |
| Y + In + Ca + Mg | | | | | | | | | | |
| Ga + Ag | 2.6 | 9.9 | 8.9 | 0.0 | 6.5 | 6.0 | 0.0 | 6.0 | 5.8 | 9.6 |
| Ga/(Ga + Ag) | 0.0 | 0.6 | 0.7 | — | 1.0 | 1.0 | — | 1.0 | 1.0 | 0.6 |
| Ag/(Ga + Ag) | 1.0 | 0.4 | 0.3 | — | 0.0 | 0.0 | — | 0.0 | 0.0 | 0.4 |
| Tx(° C.) | 279 | 299 | 291 | 304 | 303 | 301 | 275 | 309 | 290 | 308 |

TABLE 6

| | | Ex. 51 | Ex. 52 | Ex. 53 | Ex. 54 | Ex. 55 | Ex. 56 | Ex. 57 | Ex. 58 | Ex. 59 | Ex. 60 |
|---|---|---|---|---|---|---|---|---|---|---|---|
| Variable | Ge | 10.5 | 12.1 | 9.8 | 12.2 | 16.3 | 16.9 | 10.2 | 14.5 | 10.0 | 11.4 |
| Resistance | Te | 81.1 | 58.2 | 81.6 | 58.3 | 75.5 | 74.2 | 81.2 | 81.4 | 81.4 | 58.9 |
| Material | Si | | | | 7.6 | | 2.6 | | | 5.4 | |
| Composition | Al | | | 3.7 | 21.9 | | | | | | |
| (% by atom) | Ga | | 22.3 | | | | | 3.8 | 1.2 | | 22.6 |
| | Sn | 4.8 | | 4.9 | | | | | | | 7.1 |
| | Bi | | | | | | 6.3 | | | 3.2 | |
| | Ag | | 7.4 | | | 2.8 | | 4.8 | 2.9 | | |
| | Sb | 3.6 | | | | 5.4 | | | | | |

| | | | | | | | | | | |
|---|---|---|---|---|---|---|---|---|---|---|
| Ge + Te | 91.6 | 70.3 | 91.4 | 70.5 | 91.8 | 91.1 | 91.4 | 95.9 | 91.4 | 70.3 |
| Si + Al + Ga + Sn + | 4.8 | 29.7 | 8.6 | 29.5 | 2.8 | 8.9 | 8.6 | 4.1 | 8.6 | 29.7 |
| Bi + Cu + Ag + Zn + | | | | | | | | | | |
| Y + In + Ca + Mg | | | | | | | | | | |
| Ga + Ag | 0.0 | 29.7 | 0.0 | 0.0 | 2.8 | 0.0 | 8.6 | 4.1 | 0.0 | 22.6 |
| Ga/(Ga + Ag) | — | 0.8 | — | — | 0.0 | — | 0.4 | 0.3 | — | 1.0 |
| Ag/(Ga + Ag) | — | 0.2 | — | — | 1.0 | — | 0.6 | 0.7 | — | 0.0 |
| Tx(° C.) | 218 | 268 | 250 | 274 | 266 | 284 | 255 | 257 | 243 | 272 |

TABLE 7

| | | Ex. 61 | Ex. 62 | Ex. 63 | Ex. 64 | Ex. 65 | Ex. 66 | Ex. 67 | Ex. 68 | Ex. 69 | Ex. 70 |
|---|---|---|---|---|---|---|---|---|---|---|---|
| Variable | Ge | 20.6 | 26.4 | 17.5 | 20.1 | 19.8 | 17.2 | 18.1 | 14.3 | 14.0 | 12.6 |
| Resistance | Te | 47.3 | 42.3 | 56.7 | 47.8 | 48.1 | 57.9 | 57.3 | 81.6 | 81.9 | 82.4 |
| Material | Si | 0.8 | | | | | | | | | 3.6 |
| Composition | Al | 31.3 | | | | 31.5 | | | | | |
| (% by atom) | Ga | | 0.5 | | 31.2 | | 24.9 | | | | |
| | Sn | | | | | 0.6 | | 24.6 | | 3.2 | |
| | Bi | | | | | | | | 1.1 | 0.9 | |
| | Ag | | 30.8 | 25.8 | 0.9 | | | | 3.0 | | |
| | Sb | | | | | | | | | | 1.4 |

| | | | | | | | | | | |
|---|---|---|---|---|---|---|---|---|---|---|
| Ge + Te | 67.9 | 68.7 | 74.2 | 67.9 | 67.9 | 75.1 | 75.4 | 95.9 | 95.9 | 95.0 |
| Si + Al + Ga + Sn + | 32.1 | 31.3 | 25.8 | 32.1 | 32.1 | 24.9 | 24.6 | 4.1 | 4.1 | 3.6 |
| Bi + Cu + Ag + Zn + | | | | | | | | | | |
| Y + In + Ca + Mg | | | | | | | | | | |
| Ga + Ag | 0.0 | 31.3 | 25.8 | 32.1 | 0.0 | 24.9 | 0.0 | 3.0 | 0.0 | 0.0 |
| Ga/(Ga + Ag) | — | 0.0 | 0.0 | 1.0 | — | 1.0 | — | 0.0 | — | — |
| Ag/(Ga + Ag) | — | 1.0 | 1.0 | 0.0 | — | 0.0 | — | 1.0 | — | — |
| Tx(° C.) | 333 | 221 | 215 | 328 | 333 | 222 | 220 | 255 | 259 | 249 |

TABLE 8

| | | Ex. 71 | Ex. 72 | Ex. 73 | Ex. 74 | Ex. 75 | Ex. 76 | Ex. 77 | Ex. 78 | Ex. 79 | Ex. 80 |
|---|---|---|---|---|---|---|---|---|---|---|---|
| Variable | Ge | 32.1 | 26.1 | 25.2 | 28.3 | 31.2 | 32.1 | 29.2 | 28.5 | 25.9 | 28.0 |
| Resistance | Te | 60.8 | 42.6 | 42.6 | 42.3 | 61.7 | 60.8 | 41.4 | 41.6 | 42.8 | 42.6 |
| Material | Si | | | | | 4.9 | | | | 30.2 | 22.9 |
| Composition | Al | 3.0 | | | | | | | | 1.1 | |
| (% by atom) | Ga | | | | 6.7 | 2.2 | 2.4 | | | | 6.5 |
| | Sn | 4.1 | | 31.0 | | | | | 23.3 | | |
| | Bi | | 1.1 | | | | | 6.2 | | | |
| | Ag | | 30.2 | | 22.7 | | 4.7 | 23.2 | | | |
| | Sb | | | 1.2 | | | | | 6.6 | | |

| | | | | | | | | | | |
|---|---|---|---|---|---|---|---|---|---|---|
| Ge + Te | 92.9 | 68.7 | 67.8 | 70.6 | 92.9 | 92.9 | 70.6 | 70.1 | 68.7 | 70.6 |
| Si + Al + Ga + Sn + | 7.1 | 31.3 | 31.0 | 29.4 | 7.1 | 7.1 | 29.4 | 23.3 | 31.3 | 29.4 |
| Bi + Cu + Ag + Zn + | | | | | | | | | | |
| Y + In + Ca + Mg | | | | | | | | | | |
| Ga + Ag | 0.0 | 30.2 | 0.0 | 29.4 | 2.2 | 7.1 | 23.2 | 0.0 | 0.0 | 6.5 |
| Ga/(Ga + Ag) | — | 0.0 | — | 0.2 | 1.0 | 0.3 | 0.0 | — | — | 1.0 |
| Ag/(Ga + Ag) | — | 1.0 | — | 0.8 | 0.0 | 0.7 | 1.0 | — | — | 0.0 |
| Tx(° C.) | 267 | 225 | 215 | 235 | 264 | 266 | 231 | 217 | 226 | 233 |

TABLE 9

| | | Ex. 81 | Ex. 82 | Ex. 83 | Ex. 84 | Ex. 85 | Ex. 86 | Ex. 87 | Ex. 88 | Ex. 89 | Ex. 90 |
|---|---|---|---|---|---|---|---|---|---|---|---|
| Variable | Ge | 36.5 | 36.8 | 37.0 | 6.0 | 6.4 | 31.4 | 7.8 | 8.3 | 36.6 | 8.1 |
| Resistance | Te | 42.6 | 42.3 | 42.1 | 77.8 | 77.4 | 61.2 | 51.5 | 51.0 | 41.9 | 51.2 |
| Material | Si | | | | | 3.2 | 4.6 | 13.3 | 12.7 | 18.2 | |
| Composition | Al | | | | | | | | 28.0 | | |
| (% by atom) | Ga | | 3.1 | | 12.4 | | | | | | 27.8 |
| | Sn | | | 18.0 | | | | | | | |
| | Bi | 3.5 | | 2.9 | | 13.0 | | 27.4 | | | |
| | Ag | 17.4 | 17.8 | | 3.8 | | | | | | 12.9 |
| | Sb | | | | | | 2.8 | | | 3.3 | |

| | | | | | | | | | | |
|---|---|---|---|---|---|---|---|---|---|---|
| Ge + Te | 79.1 | 79.1 | 79.1 | 83.8 | 83.8 | 92.6 | 59.3 | 59.3 | 78.5 | 59.3 |
| Si + Al + Ga + Sn + | 20.9 | 20.9 | 20.9 | 16.2 | 16.2 | 4.6 | 40.7 | 40.7 | 18.2 | 40.7 |
| Bi + Cu + Ag + Zn + | | | | | | | | | | |
| Y + In + Ca + Mg | | | | | | | | | | |
| Ga + Ag | 17.4 | 20.9 | 0.0 | 16.2 | 0.0 | 0.0 | 0.0 | 0.0 | 0.0 | 40.7 |
| Ga/(Ga + Ag) | 0.0 | 0.1 | — | 0.8 | — | — | — | — | — | 0.7 |
| Ag/(Ga + Ag) | 1.0 | 0.9 | — | 0.2 | — | — | — | — | — | 0.3 |
| Tx(° C.) | 232 | 235 | 244 | 255 | 257 | 252 | 272 | 293 | 225 | 289 |

TABLE 10

| | | Ex. 91 | Ex. 92 | Ex. 93 | Ex. 94 | Ex. 95 | Ex. 96 | Ex. 97 | Ex. 98 | Ex. 99 | Ex. 100 |
|---|---|---|---|---|---|---|---|---|---|---|---|
| Variable | Ge | 3.1 | 5.4 | 3.2 | 2.6 | 4.2 | 4.3 | 4.6 | 6.0 | 3.6 | 3.3 |
| Resistance | Te | 85.9 | 77.9 | 85.8 | 86.4 | 75.0 | 74.9 | 74.6 | 77.8 | 75.6 | 85.3 |
| Material | Si | 1.1 | | | | | 2.6 | | 4.1 | | |
| Composition | Al | | | | | | | 18.6 | | | |
| (% by atom) | Ga | | | 10.3 | 10.1 | 17.9 | | | 12.1 | | |
| | Sn | | 4.0 | | 0.9 | | | 2.2 | | | |
| | Bi | 9.9 | | | | | | | | 18.3 | |
| | Ag | | | 0.7 | | 2.9 | | | | 2.5 | 1.0 |
| | Sb | | 12.7 | | | | 18.2 | | | | 10.4 |

| | | | | | | | | | | |
|---|---|---|---|---|---|---|---|---|---|---|
| Ge + Te | 89.0 | 83.3 | 89.0 | 89.0 | 79.2 | 79.2 | 79.2 | 83.8 | 79.2 | 88.6 |
| Si + Al + Ga + Sn + | 11.0 | 4.0 | 11.0 | 11.0 | 20.8 | 2.6 | 20.8 | 16.2 | 20.8 | 1.0 |
| Bi + Cu + Ag + Zn + | | | | | | | | | | |
| Y + In + Ca + Mg | | | | | | | | | | |
| Ga + Ag | 0.0 | 0.0 | 11.0 | 10.1 | 20.8 | 0.0 | 0.0 | 12.1 | 2.5 | 1.0 |
| Ga/(Ga + Ag) | — | — | 0.9 | 1.0 | 0.9 | — | — | 1.0 | 0.0 | 0.0 |
| Ag/(Ga + Ag) | — | — | 0.1 | 0.0 | 0.1 | — | — | 0.0 | 1.0 | 1.0 |
| Tx(° C.) | 238 | 238 | 241 | 240 | 259 | 233 | 261 | 259 | 255 | 220 |

TABLE 11

| | | | | | | | | | Comp. | Comp. |
|---|---|---|---|---|---|---|---|---|---|---|
| | | Ex. 101 | Ex. 102 | Ex. 103 | Ex. 104 | Ex. 105 | Ex. 106 | Ex. 107 | Ex. 1 | Ex. 2 |
| Variable | Ge | 2.7 | 2.6 | 2.6 | 2.4 | 15.0 | 15.4 | 15.8 | 5.0 | 16.8 |
| Resistance | Te | 87.9 | 88.0 | 87.9 | 88.2 | 75.0 | 76.9 | 78.9 | 92.0 | 83.2 |
| Material | Si | | | 5.3 | | | | | | |
| Composition | Al | | 3.8 | | | | | | 2.0 | |
| (% by atom) | Ga | 4.5 | | | | 5.0 | 7.7 | | | |
| | Sn | | 5.6 | | | | | | | |
| | Bi | | | | 4.3 | | | | | |
| | Ag | 4.9 | | | 5.1 | 5.0 | | 5.3 | 1.0 | |
| | Sb | | | 4.2 | | | | | | |

| | | | | | | | | | |
|---|---|---|---|---|---|---|---|---|---|
| Ge + Te | 90.6 | 90.6 | 90.5 | 90.6 | 90.0 | 92.3 | 94.7 | 97.0 | 100.0 |
| Si + Al + Ga + Sn + | 9.4 | 9.4 | 5.3 | 9.4 | 10.0 | 7.7 | 5.3 | 3.0 | 0.0 |
| Bi + Cu + Ag + Zn + | | | | | | | | | |
| Y + In + Ca + Mg | | | | | | | | | |
| Ga + Ag | 9.4 | 0.0 | 0.0 | 5.1 | 10.0 | 7.7 | 5.3 | 1.0 | 0.0 |
| Ga/(Ga + Ag) | 0.5 | — | — | 0.0 | 0.5 | 1.0 | 0.0 | 0.0 | — |
| Ag/(Ga + Ag) | 0.5 | — | — | 1.0 | 0.5 | 0.0 | 1.0 | 1.0 | — |
| Tx(° C.) | 245 | 249 | 231 | 243 | 245 | 255 | 238 | 147 | 220 |

Each sample was produced in the following manner. First, a quartz glass ampule was evacuated while being heated, and raw materials were then formulated and put into the quartz glass ampule. Next, the quartz glass ampule was sealed with an oxygen burner. Next, the sealed quartz glass ampule was placed into a melting furnace and the temperature of the melting furnace was raised to 650° C. to 1000° C. at a rate of 10° C./h to 40° C./h and then held for six hours to twelve hours. During the holding time, the quartz glass ampule was turned upside down to stir the melt. Finally, the quartz glass ampule was taken out of the melting furnace and rapidly cooled to room temperature, thus obtaining a sample for a variable resistance material. The obtained sample was measured in terms of crystallization temperature Tx by heat treating it at various temperatures and examining by XRD the point at which a crystallization peak appears.

As shown in Tables 1 to 11, the variable resistance materials in Ex. 1 to Ex. 107 exhibited a high crystallization temperature Tx of 215° C. or higher. In contrast, the variable resistance material in CEx. 1 exhibited a low crystallization temperature Tx of 147° C.

Next, using the variable resistance materials in Ex. 33, Ex. 105 to Ex. 107, CEx. 1, and CEx. 2 as target members, thin-film samples for measuring the carrier mobility and switch elements were produced. The production procedures of each switch element are shown below. First, a 50 nm thick W electrode was deposited on a Si/SiO₂ substrate. Next, a 100 nm thick SiO₂ insulating layer was deposited on the W electrode. Thereafter, using a focused ion beam system (JIB-4600F by JEOL), a 500 nm diameter hole was formed in the SiO₂ insulating layer and the W electrode. Next, a 150 nm thick variable resistance material was deposited into the formed hole, thus forming a switch layer. Finally, a 150 nm thick W electrode was further deposited on the switch layer, thus producing a switch element. The deposition was conducted by Ar sputtering under a reduced-pressure atmosphere.

Each thin-film sample for measuring the carrier mobility was produced by depositing a 150 nm thick variable resistance material on a Si/SiO₂ substrate by Ar sputtering.

Using the obtained thin-film sample and the switch element, the ON/OFF current ratio, the number of cycles, and the carrier mobility at 30° C. were measured. The results are shown in Table 12.

TABLE 12

| | | | | | Comp. | Comp. |
|---|---|---|---|---|---|---|
| | Ex. 33 | Ex. 105 | Ex. 106 | Ex. 107 | Ex.1 | Ex.2 |
| ON/OFF | 1 × 10^{6.8} | 1 × 10^{6.6} | 1 × 10^{5.1} | 1 × 10^{4.3} | 1 × 10^{3.2} | 1 × 10^{3.9} |
| Current | | | | | | |
| Ratio | | | | | | |
| Number of | 1 × 10⁴ | 1 × 10^{4.1} | 1 × 10⁴ | 1 × 10^{5.2} | 1 × 10^{1.8} | 1 × 10^{2.3} |
| Cycles | | | | | | |
| (cycles) | | | | | | |
| Carrier | 8.5 × 10⁻⁵ | 8.7 × 10⁻⁵ | 2.1 × 10⁻⁴ | 2.6 × 10⁻³ | 8.1 × 10⁻³ | 5.1 × 10⁻³ |
| Mobility | | | | | | |
| (cm²/Vs) | | | | | | |

The ON/OFF current ratio was determined in the following manner. First, a 0 V to 5 V voltage was applied to the switch element to measure the values of current that flowed through the switch element and the threshold voltage. Next, the value of the ON current was divided by the value of the OFF current, thus obtaining the ON/OFF current ratio. The value of the ON current is a value of a current that flowed through the switch element upon application of a voltage not less than the threshold voltage thereto. The value of the OFF current is a value of a current that flowed through the switch element upon application of one-half the threshold voltage thereto.

The number of cycles is the number of repetitions of switching between ON/OFF currents until the ON/OFF current ratio reached 10% of its initially measured value.

The carrier mobility at 30° C. was measured with a resistivity/Hall measurement system (ResiTest 8308, manufactured by TOYO Corporation).

As for Ex. 33, in addition to the above measurement, the value obtained by dividing the value of ON resistance by the value of OFF resistance was also measured.

The switch elements in Ex. 33 and Ex. 105 to Ex. 107 exhibited a high ON/OFF current ratio of 1×10^{4.3} or more and a large number of cycles of 1×10⁴ or more. Furthermore, their carrier mobility was as low as 2.6×10⁻³ cm²/Vs or less. On the other hand, the switch elements in CEx. 1 and CEx. 2 exhibited a low ON/OFF current ratio of 1×10^{3.9} or less and a small number of cycles of 1×10^{2.3} or less. Furthermore, their carrier mobility was as high as 5.1×10⁻³ cm²/Vs or more.

Moreover, in the switch element in Ex. 33, the value obtained by dividing the value of ON resistance by the value of OFF resistance was as low as 1×10^{-6.8}.

### INDUSTRIAL APPLICABILITY

The variable resistance material according to the present invention can be suitably used for a switch element that can be used in a resistance-variable memory device, a phase-variable memory device or other types of memory devices.

### REFERENCE SIGNS LIST

1 first electrode
2 second electrode
3 switch layer
10 switch element
20 memory element
30 word line
40 bit line
100 memory device

1. A variable resistance material containing, in terms of % by atom, 1% to 40% Ge, 40% to 90% Te, and 1% to 59% Si+Al+Ga+Sn+Bi+Cu+Ag+Zn+Y+In+Ca+Mg.

2. The variable resistance material according to claim 1, containing, in terms of % by atom, 0% to 20% Sb.

3. The variable resistance material according to claim 1, being substantially free of Sb, Se, and As.

4. The variable resistance material according to claim 1, containing, in terms of % by atom, over 50% to 90% Te.

5. The variable resistance material according to claim 1, containing, in terms of % by atom, 1% to less than 30% Ge.

6. The variable resistance material according to claim 1, having an ON/OFF current ratio of 1×104 or more.

7. The variable resistance material according to claim 1, having a crystallization temperature Tx of 150° C. or higher.

8. A switch element material made of the variable resistance material according to claim 1.

9. A switch layer made of the variable resistance material according to claim 1.

10. A switch element comprising:
a first electrode; and
the switch layer according to claim 9, the switch layer being disposed on the first electrode.

11. The switch element according to claim 10, comprising a second electrode disposed at a position opposed to the first electrode with the switch layer in between.

12. A memory device comprising:
the switch element according to claim 11; and
a memory element.
